(19) United States
(12) Patent Application Publication
(10) Pub. No.: US 2008/0237893 A1
(43) Pub. Date: Oct. 2, 2008

(54) Anti Pad To Reduce Parasitic Capacitance And Improve Return Loss In A Semiconductor Die And Package

(76) Inventors: Minh Van Quach, Fort Collins, CO (US); Nurwati S. Devnani, Fort Collins, CO (US); Wang Lin, Singapore (SG); Robert B. Manley, Fort Collins, CO (US); Robert A. Zimmer, Loveland, CO (US)

Correspondence Address: Kathy Manke;Avago Technologies Limited, 4380 Ziegler Road, Fort Collins, CO, 80525, US

(21) Appl. No.: 11/691,788

(22) Filed: Mar. 27, 2007

(51) Int. Cl. H01L 23/48

(52) U.S. Cl. 257/781

(57) ABSTRACT

An apparatus for minimizing parasitic capacitance on a semiconductor die includes a semiconductor die having a least one signal line and at least one plane and an anti pad located between the at least one signal line and the at least one plane.

### BACKGROUND

As integrated circuits become increasingly compact, processing dimensions continue to shrink. One result of shrinking process dimensions is the impact of parasitic capacitance and parasitic capacitance variations within the integrated circuit. Parasitic capacitance can be described as capacitance that is not taken into account when considering ideal circuit elements. Parasitic capacitance causes operating anomalies in the integrated circuit and when severe, can cause the integrated circuit to malfunction, or function at a level below its intended performance level. The effects of parasitic capacitance become more significant as the physical size of the circuitry is made smaller and the operating frequency is getting higher.

When an integrated circuit is designed, capacitance values are calculated based on the performance of ideal circuit elements and the values for parasitic capacitances are estimated based on factors such as the physical layout of the circuit. However, when the circuit is fabricated, process variations, such as physical size of conductors and traces, process variation over time, temperature variations, and other variations in the processing of the integrated circuit, give rise to parasitic capacitance variation. Further, variations in parasitic capacitances over two or more identically designed portions of the integrated circuit reduce the performance of the circuit and make circuit performance even more difficult to predict.

With regard to an integrated circuit (IC) package, large parasitic capacitance can be caused where a circuit via connects to a solder ball interconnect. A circuit via is a structure that typically connects different layers of a circuit or device and can include a plated through hole. Additional large capacitance can be caused by a plated through hole via that is adjacent to or in close proximity to a ground plane.

With regard to a circuit die, a micro via that connects a circuit pad to the circuitry on the die typically passes close to power and ground planes. This proximity of the via to power and ground planes can give rise to large parasitic capacitance and can impact the return loss of the circuit.

Therefore, it would be desirable to have a way to minimize the parasitic capacitance on an integrated circuit die and package.

### SUMMARY

In an embodiment, an apparatus for minimizing parasitic capacitance on a semiconductor die comprises a semiconductor die having a least one signal line and at least one plane and an anti pad located between the at least one signal line and the at least one plane.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic diagram illustrating a portion of an integrated circuit (IC) package.

FIG. 2 is a top plan view illustrating a portion of the IC package of FIG. 1.

FIG. 3 is a bottom plan view illustrating a portion of the IC package of FIG. 1.

FIG. 4 is a schematic view illustrating a portion of a semiconductor die.

FIG. 5 is a plan view illustrating a portion of the semiconductor die of FIG. 4.

FIG. 6 is a schematic diagram illustrating the portion of the integrated circuit of FIG. 1 and the portion of the semiconductor die of FIG. 4 coupled together to form a semiconductor die and package.

FIG. 7 is a flow chart illustrating the operation of an embodiment of the anti pad to reduce parasitic capacitance and improve return loss in a semiconductor die and package.

FIG. 8 is a diagram illustrating a return loss specification and the return loss response of a circuit including an anti pad in accordance with the invention.

FIG. 9 is a diagram illustrating the parasitic capacitance of a circuit on a semiconductor die including a die anti pad in accordance with the invention.

### DETAILED DESCRIPTION

Embodiments of the anti pad to reduce parasitic capacitance and improve return loss in a semiconductor die and package are implemented in both the package and the die. Further, the anti pad to reduce parasitic capacitance and improve return loss in a semiconductor die and package to be described below will be described in the context of an integrated circuit, or a number of integrated circuit portions formed on a single die, also referred to as a “chip,” and integrated into an integrated circuit (IC) package. However, the anti pad to reduce parasitic capacitance and improve return loss in a semiconductor die and package can be implemented in any circuitry in which it is desirable to control parasitic capacitance and return loss. Further, the anti pad to reduce parasitic capacitance and improve return loss in a semiconductor die and package will be described with regard to a signal line and a ground plane. However, the anti pad to reduce parasitic capacitance and improve return loss in a semiconductor die and package is also applicable to other circuit structures, such as a power plane.

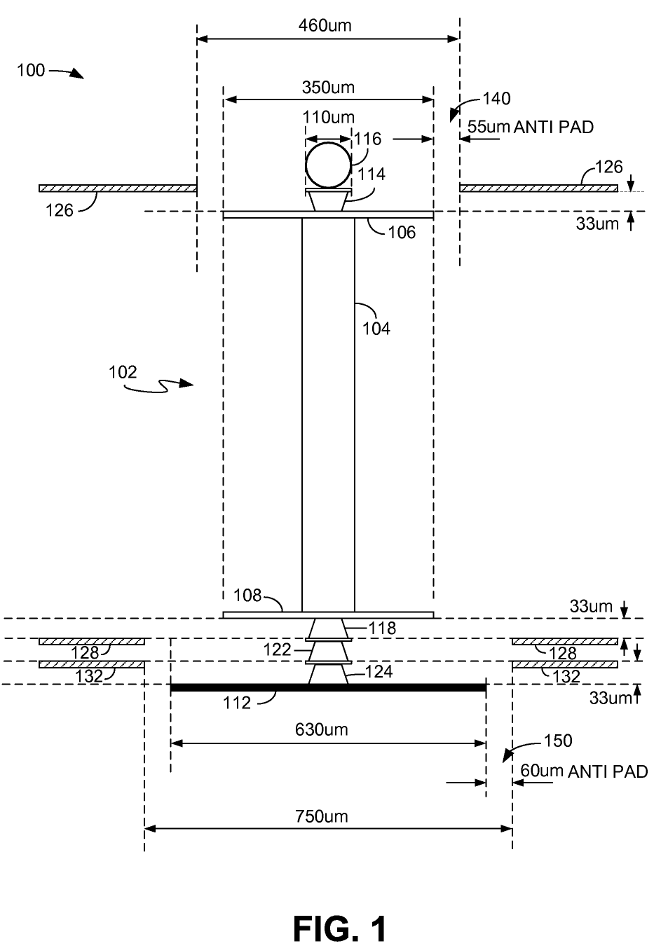

FIG. 1 is a schematic diagram illustrating a portion 100 of an integrated circuit (IC) package. The portion 100 of the IC package includes a via 104. The term “via” is given to an interconnect structure that typically couples different layers in a circuit structure. A via may also be thought of as a structure that carries a signal and which may be connected to a signal line or a signal trace. The via may also be a micro-via having a diameter on the order of less than about 100 micrometers (μm). In an embodiment, the via 104 carries an electrical signal to and from other components associated with the IC package and generally connects different layers on an integrated circuit. The via 104 is connected to an upper pad 106. The upper pad 106 is electrically connected to a cap 114. A ground plane 126 is in proximity to the upper pad 106. The ground plane 126 is a conductive layer that spans a portion of an integrated circuit package or a semiconductor die. Other plane layers, such as additional ground planes, one or more power planes, and additional signal planes are also located on an IC package and on a semiconductor die. In an embodiment in which the IC package 100 couples to other electrical components via a ball grid array, (BGA), a conductive ball 116 is located over the cap 114. In an embodiment, the conductive ball 116 is a solder ball.

In accordance with an embodiment of the invention, and using dimensions that are exemplary only, a space, or gap, having a radial dimension of approximately 55 micrometers (μm) is provided between the upper pad 106 and the ground plane 126. The space is referred to as an anti-pad 140. In the example shown in FIG. 1, the ground plane 126 has a radial opening having a diameter of approximately 460 μm while a diameter of the upper pad 106 is approximately 350 μm. This results in an anti-pad having a radial dimension of approximately 55 μm. These dimensions may vary by approximately 20%. An anti pad sufficiently large to minimize capacitance, while not so large as to jeopardize the power handling capability of the circuit is desired. The anti-pad 140 provides clearance and electrical isolation between a signal and a ground plane. The anti pad 140 reduces parasitic capacitance that may exist between the upper pad 106 and the ground plane 126 and also improves the return loss of the circuit.

The via 104 is also connected to a lower pad 108. The lower pad 108 is coupled to a cap 118. The cap 118 is also coupled to another cap 122, which is coupled to a third cap 124. The third cap 124 is electrically coupled to a contact pad 112. The caps 118, 122 and 124 are associated with different layers in the IC package 100. The number of caps is determined by the number of layers in the IC portion 100. In this example, the contact pad 112 has a diameter of approximately 630 μm. A ground plane 128 and a ground plane 132 are located in proximity to the lower pad 108 and the contact pad 112. The opening in the ground plane 128 and the ground plane 132 is approximately 750 μm in diameter. These dimensions result in a space having a radial dimension of approximately 60 μm between the contact pad 112 and the ground planes 128 and 132. This is referred to as an anti-pad 150. These dimensions may vary by approximately 20%. An anti pad sufficiently large to minimize capacitance, while not so large as to jeopardize the power handling capability of the circuit is desired. It should be mentioned that the designation upper pad and lower pad for pads 106 and 108 is arbitrary and the location of the pads is spatially invariant. The cap 114, upper pad 106, via 104, lower pad 108, caps 118, 122 and 124, and the contact pad 112 form a via assembly 102.

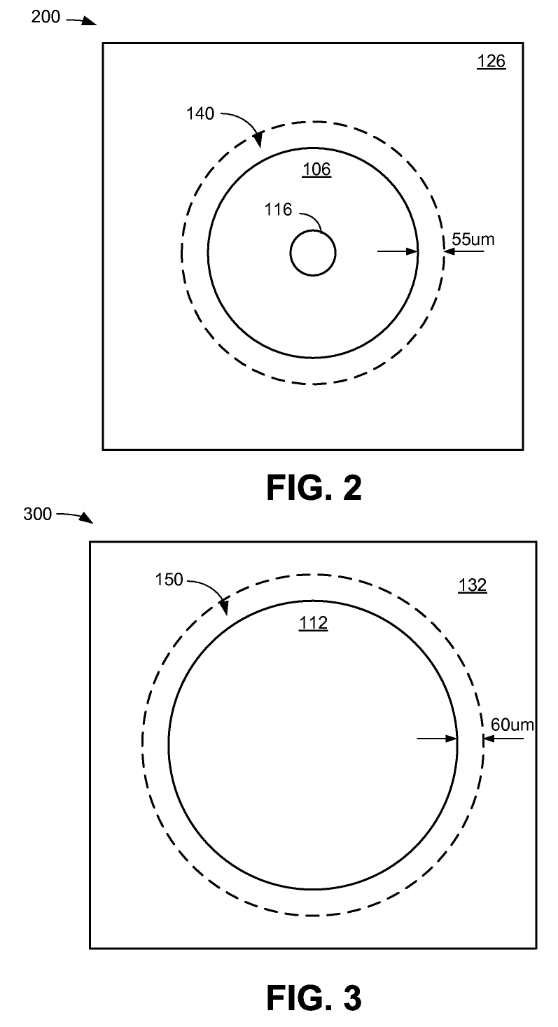

FIG. 2 is a top plan view 200 illustrating a surface of the ground plane 126, a surface of the upper pad 106 and the ball 116. As shown in FIG. 2, the anti-pad 140 has a radial dimension of approximately 55 μm. The anti pad 140 provides a nonconductive gap between the upper pad 106 and the ground plane 126, thus reducing parasitic capacitance and improving return loss in the circuit.

FIG. 3 is a bottom plan view 300 illustrating a surface of the ground plane 132 and a surface of the contact pad 112. As shown in FIG. 3, the anti-pad 150 has a radial dimension of 60 μm. The anti pad 150 provides a nonconductive gap between the contact pad 112 and the ground plane 132 (and the ground plane 128 (FIG. 1)), thus reducing parasitic capacitance and improving return loss in the circuit.

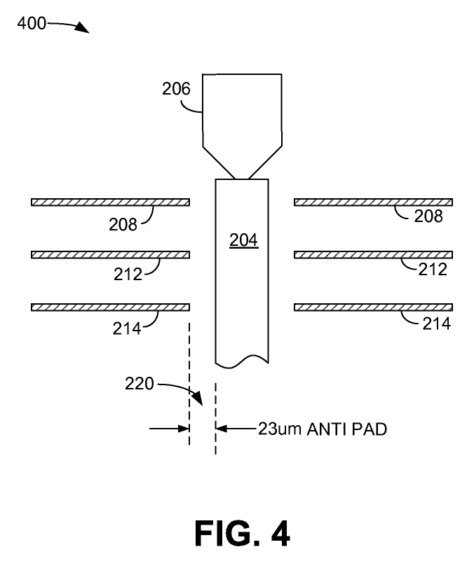

FIG. 4 is a schematic view illustrating a portion 400 of a semiconductor die. The die portion 400 includes a via 204. The via 204 functions in a similar manner to the via 104 described above. However, the via 204 is located within a semiconductor die, and not in an IC package as described above, and is typically a micro via. The via 204 is electrically coupled to an interconnect 206. The via 204 is also in close electrical proximity to a ground plane 208, a ground plane 212, and a ground plane 214. As shown in FIG. 4, a gap of approximately 23 μm exists between the ground planes 208 212 and 214 and the via 204. This results in an anti-pad 220 having a radial dimension of approximately 23 μm. However, this dimension may vary by approximately 20%. An anti pad sufficiently large to minimize capacitance, while not so large as to jeopardize the power handling capability of the circuit is desired.

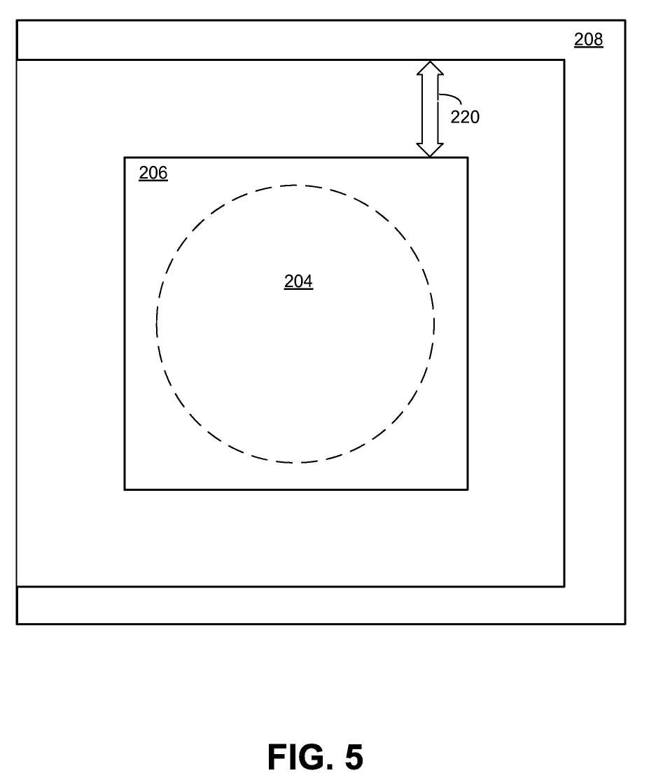

FIG. 5 is a plan view illustrating the ground plane 208, via 204 and anti pad 220 of the die portion 400 of FIG. 4. As shown in FIG. 5, the via 204 is covered by the interconnect 206. The ground plane 208 is separated from the interconnect 206 and the via 204 by an anti pad 220 having a radial dimension of approximately 23 μm.

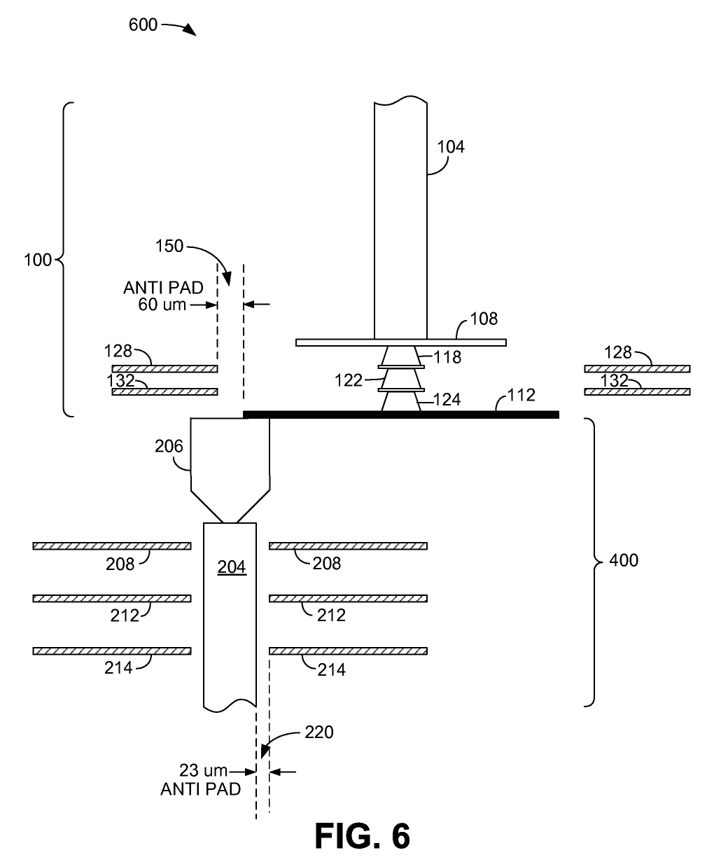

FIG. 6 is a schematic diagram 600 illustrating the IC portion 100 of the integrated circuit of FIG. 1 and the die portion 400 of the semiconductor die of FIG. 4 coupled together to form a semiconductor die and package. The contact pad 112 of the IC package 100 is electrically coupled to the interconnect 206 of the semiconductor die portion 400. In this manner, the anti pad 220 of FIG. 4 and the anti-pads 150 and 140 of FIG. 1 are associated together in a single IC package and semiconductor die assembly. In this manner, parasitic capacitance is minimized and return loss is controlled in a semiconductor die and package.

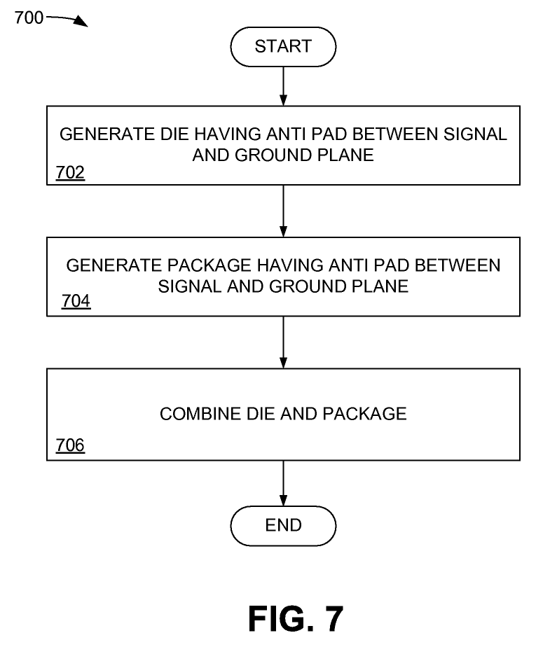

FIG. 7 is a flow chart 700 illustrating the operation of an embodiment of the anti pad to reduce parasitic capacitance and improve return loss in a semiconductor die and package. In block 702 a die having at least one anti pad between a signal line and a ground plane is generated. In block 704, an IC package having an anti pad between a signal and a ground plane is generated. In block 706, the die and IC package are combined into a single structure having a plurality of anti pads to minimize parasitic capacitance and control return loss.

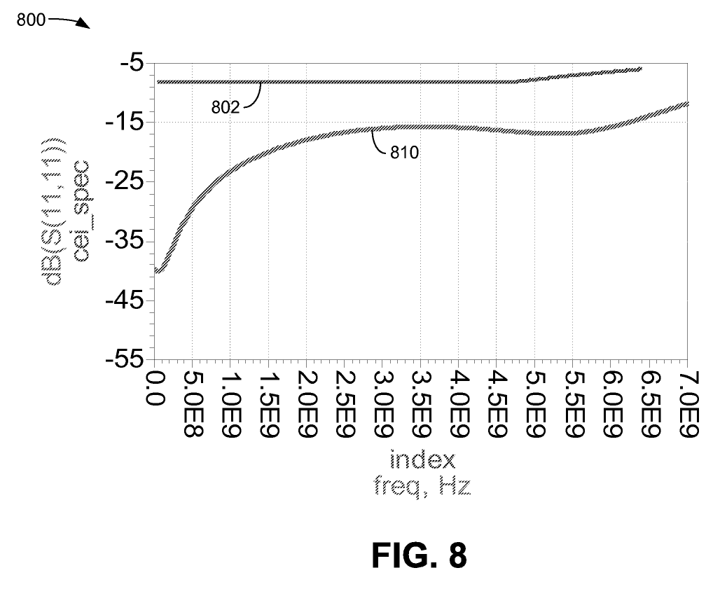

FIG. 8 is a diagram illustrating a return loss specification and the return loss response of a circuit including an IC package anti pad in accordance with the invention. The horizontal axis represents frequency and the vertical axis represents dB. the trace 802 represents the circuit specification and the trace 810 represents the return loss response of a circuit including an anti pad in accordance with the invention.

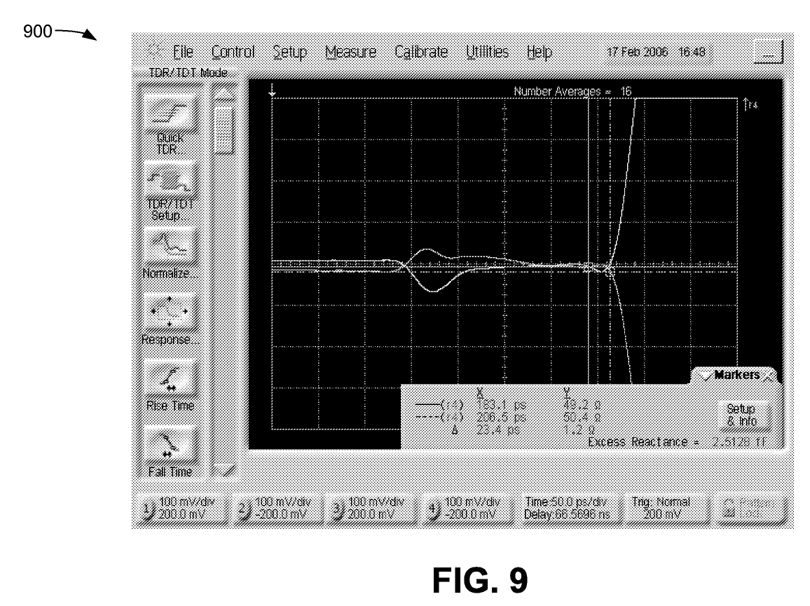

FIG. 9 is a diagram illustrating the parasitic capacitance of a circuit on a semiconductor die including a die anti pad in accordance with the invention. As shown in FIG. 9, the parasitic capacitance is in the range of 2.5 femtoFarads (fF) as shown on a time domain reflectometer plot.

This disclosure describes the invention in detail using illustrative embodiments. However, it is to be understood that the invention defined by the appended claims is not limited to the precise embodiments described.

What is claimed is:

1. An apparatus for minimizing parasitic capacitance on a semiconductor die, comprising:
a semiconductor die having a least one signal line and at least one plane; and
an anti pad located between the at least one signal line and the at least one plane.

2. The apparatus of claim 1, further comprising:
an integrated circuit package comprising:
at least one additional signal line and at least one additional plane; and
at least one additional anti pad located between the at least one additional signal line and the at least one additional plane.

3. The apparatus of claim 2, wherein the plane is a ground plane.

4. The apparatus of claim 2, wherein the at least one signal line is a micro via.

5. The apparatus of claim 2, wherein the anti pad associated with the semiconductor die has a radial dimension of approximately 23 μm.

6. The apparatus of claim 2, wherein the anti pad associated with the integrated circuit package has a radial dimension of approximately 55-60 μm.

7. The apparatus of claim 2, wherein the at least one anti pad and the at least one additional anti pad are sized to minimize parasitic capacitance.

8. A method for minimizing parasitic capacitance on a semiconductor die, comprising:
providing a semiconductor die having a least one signal line and at least one plane; and
forming an anti pad between the at least one signal line and the at least one plane.

9. The method of claim 8, further comprising:
providing an integrated circuit package comprising:
forming at least one additional signal line and at least one additional plane; and
forming at least one additional anti pad between the at least one additional signal line and the at least one additional plane.

10. The method of claim 9, wherein the at least one plane comprises a ground plane.

11. The method of claim 9, wherein the via is a micro-via.

12. The method of claim 9, wherein forming the anti pad associated with the semiconductor die comprises forming the anti pad to have a radial dimension of approximately 23 μm.

13. The method of claim 9, wherein forming the anti pad associated with the integrated circuit package comprises forming the anti pad to have a radial dimension of approximately 55-60 μm.

14. The method of claim 9, further comprising forming the anti pad associated with the semiconductor die and forming the anti pad associated with the integrated circuit package to minimize parasitic capacitance.

15. An apparatus for minimizing parasitic capacitance on a semiconductor die and integrated circuit package, comprising:
a semiconductor die having a least one signal line and at least one plane;
an anti pad located between the at least one signal line and the at least one plane;
an integrated circuit package having at least one additional signal line and at least one additional plane; and
at least one additional anti pad located between the at least one additional signal line and the at least one additional plane.

16. The apparatus of claim 15, wherein the plane is a ground plane.

17. The apparatus of claim 15, wherein the at least one signal line is a micro via.

18. The apparatus of claim 15, wherein the anti pad associated with the semiconductor die has a radial dimension of approximately 23 μm.

19. The apparatus of claim 15, wherein the anti pad associated with the integrated circuit package has a radial dimension of approximately 55-60 μm.

20. The apparatus of claim 15, wherein the at least one anti pad and the at least one additional anti pad are sized to minimize parasitic capacitance.
